(19) United States
(12) Patent Application Publication
(10) Pub. No.: US 2026/0135461 A1
(43) Pub. Date: May 14, 2026

(54) CONTROL CIRCUIT AND METHOD FOR REDUCING REVERSE RECOVERY CHARGE IN SWITCHING POWER CONVERTER

(71) Applicant: Richtek Technology Corporation, Zhubei City (TW)

(72) Inventors: Kwan-Jen Chu, Hsinchu (TW); Ta-Yung Yang, Taoyuan (TW)

(21) Appl. No.: 19/342,646

(22) Filed: Sep. 28, 2025

Related U.S. Application Data
(60) Provisional application No. 63/719,168, filed on Nov. 12, 2024.

(30) Foreign Application Priority Data
Apr. 24, 2025 (TW) 114115575

(51) Int. Cl. H02M 1/00; H02M 1/088; H03G 1/00; H03G 3/30

(52) U.S. Cl. CPC H02M 1/0051; H02M 1/0003; H02M 1/0045; H02M 1/088; H03G 1/0029; H03G 3/3089

(57) ABSTRACT

A control circuit is configured to control a switching converter based on a pulse-width modulation (PWM) signal. The switching converter includes a first and a second transistor coupled to a switching node for switching an inductor according to the PWM signal to convert an input voltage into an output voltage. The control circuit includes: a driver circuit for generating a switching drive signal to switch the first transistor based on the PWM signal and a switching signal at the switching node; and an amplifier circuit for amplifying a difference between the switching signal and a reference signal to generate an amplified output signal during a dead time for controlling the first transistor through a linear negative feedback operation to regulate the switching signal to be not lower than a predetermined negative voltage, thereby preventing forward conduction of a body diode of the first transistor or reducing the reverse recovery charge.

### CROSS REFERENCE

The present invention claims priority to the provisional application, Ser. No. 63/719168, filed on Nov. 12, 2024 and claims priority to the TW patent application Ser. No. 114115575, filed on Apr. 24, 2025.

### BACKGROUND OF THE INVENTION

### Field of Invention

The present invention relates to a control circuit, and more particularly to a control circuit capable of reducing reverse recovery charge in a switching converter. The present invention also relates to a control method for reducing reverse recovery charge in a switching converter.

### Description of Related Art

FIG. 1A illustrates a switching converter of prior art. As shown in FIG. 1A, control signals SH and SL are processed through a logic circuit to generate non-overlapping switching drive signals DRVH and DRVL, which control the switching of a high-side transistor 42 and a low-side transistor 41, respectively. When the high-side transistor 42 is turned on, an input voltage VIN magnetizes an inductor 30 through a switching node LX and charges an output capacitor, thereby generating an output voltage VO. After the high-side transistor 42 is turned off, when the low-side transistor 41 is turned on under control of the switching drive signal DRVL, the inductor 30 is demagnetized, and its current continues to flow through the low-side transistor 41.

FIG. 1B illustrates an operating waveform diagram of prior art switching converter. As shown in FIG. 1B, during a dead time DT before the next switching cycle begins, both the high-side transistor 42 and the low-side transistor 41 are turned off, causing current of the inductor 30 to flow through a body diode 43 of the low-side transistor 41. During the dead time DT, a voltage VLX at the switching node LX drops to a value equal to a difference between zero voltage and a forward conduction voltage Vf of the body diode 43 (e.g., −0.7V). When the next switching cycle begins, the high-side transistor 42 is turned on by the switching drive signal DRVH. At this time, the body diode 43 must transition from a forward-conducting state to a reverse-biased state, which generates a large amount of reverse recovery charge (Qrr). The reverse recovery current, together with a parasitic inductor, forms a resonant circuit that results in an undesired voltage spike at the switching node LX. Such a voltage spike may even exceed maximum rated voltages of the high-side transistor 42, the low-side transistor 41, or other associated components, leading to reliability issues or even device failure.

The prior art switching converter 1001 utilizes a filter circuit composed of a capacitor 81 and a resistor 82 to suppress the voltage spike at the switching node LX. Although the filter circuit can absorb part of the parasitic oscillation energy and reduce the spike voltage, since the capacitor 81 must be charged and discharged during every switching cycle and the stored energy is eventually dissipated as heat by the resistor 82, it leads to power loss. The amount of loss is related to the capacitance of the capacitor 81, the input voltage VIN, and the switching frequency, and such loss continues to occur even under no-load conditions. Furthermore, a parasitic inductor 91 may resonate with the filter circuit, which limits the filtering effectiveness and fails to effectively suppress high-frequency noise and voltage spikes caused by reverse recovery of the body diode.

### SUMMARY OF THE INVENTION

From one perspective, the present invention provides a control circuit configured to control a switching converter based on a pulse-width modulation (PWM) signal. The switching converter includes a first transistor and a second transistor commonly coupled to a switching node, configured to switch an inductor according to the PWM signal to convert an input voltage into an output voltage. The control circuit comprises: a driver circuit configured to generate a switching drive signal based on the PWM signal and a switching signal at the switching node, thereby switching the first transistor; and an amplifier circuit configured to amplify a difference between the switching signal and a reference signal during a dead time to generate an amplified output signal, and further configured to control the first transistor through a linear negative feedback operation to regulate a voltage of the switching signal to be not lower than a predetermined negative voltage, thereby preventing forward conduction of a body diode of the first transistor or reducing a reverse recovery charge of the body diode.

In one embodiment, the driver circuit is configured to generate the switching drive signal based on a first control signal and a second control signal, thereby switching the first transistor; wherein the first control signal is related to the PWM signal, and the second control signal is related to the switching signal; wherein during the dead time, the switching drive signal is in a high output impedance state, and the first transistor is primarily controlled by the amplified output signal; wherein during a switching time outside the dead time, the switching drive signal is in a low output impedance state, and the first transistor is primarily controlled by the switching drive signal.

In one embodiment, the driver circuit includes a first switch and a second switch; wherein during an on time within the switching time, the first switch controls the switching drive signal to be asserted according to the first control signal, thereby turning on the first transistor; wherein during an off time within the switching time, the second switch controls the switching drive signal to be de-asserted according to the second control signal, thereby turning off the first transistor.

In one embodiment, when the switching signal exceeds a predetermined threshold voltage, the second control signal controls the switching drive signal to be de-asserted, thereby turning off the first transistor.

In one embodiment, a gate of the second switch is controlled by the second control signal, and the second control signal is coupled to the switching signal, wherein the predetermined threshold voltage corresponds to a turn-on threshold voltage of the second switch.

In one embodiment, the control circuit further comprises a clamping circuit configured to generate the second control signal based on the switching signal and to clamp the second control signal to be not greater than a clamping voltage level.

In one embodiment, the clamping voltage level is lower than a maximum rated voltage of the second switch.

In one embodiment, the control circuit further comprises a high-pass filter circuit coupled between the clamping circuit and the second control signal, configured to high-pass-filter the switching signal to generate the second control signal, such that when the switching signal includes a high-frequency component, the second switch controls the switching drive signal to be de-asserted, thereby turning off the first transistor.

In one embodiment, after the first transistor is turned off, the amplifier circuit maintains the amplified output signal in a disabled state based on the difference between the switching signal and the reference signal, such that the first transistor remains off.

In one embodiment, an absolute value of the predetermined negative voltage is less than a forward conduction voltage of the body diode of the first transistor.

In one embodiment, the amplifier circuit includes a common-base amplifier or a common-gate amplifier and has an input offset voltage, wherein the input offset voltage is related to the predetermined negative voltage.

In one embodiment, the amplified output signal is clamped to be not lower than a predetermined level, wherein the predetermined level is higher than a turn-on threshold voltage of the first transistor.

In one embodiment, the amplifier circuit includes a pull-down transistor and a clamping transistor serially connected to the amplified output signal, wherein the pull-down transistor is configured to provide a pull-down driving force for the amplified output signal based on the difference between the switching signal and the reference signal, and the clamping transistor is configured as a diode-connected transistor.

From another perspective, the present invention provides a control method configured to control a switching converter based on a PWM signal. The switching converter includes a first transistor and a second transistor commonly coupled to a switching node, configured to switch an inductor according to the PWM signal to convert an input voltage into an output voltage. The control method comprises: generating a switching drive signal based on the PWM signal and a switching signal at the switching node to switch the first transistor; and amplifying a difference between the switching signal and a reference signal during a dead time to generate an amplified output signal. The step of generating the amplified output signal includes: controlling the first transistor through a linear negative feedback operation to regulate a voltage of the switching signal to be not lower than a predetermined negative voltage, thereby preventing forward conduction of a body diode of the first transistor or reducing a reverse recovery charge of the body diode.

The present invention provides a control circuit for reducing reverse recovery charge in a switching converter.

The present invention configures both a driver circuit and an amplifier circuit to be coupled to a gate of the low-side transistor. During the dead time, the amplifier circuit continuously controls the low-side transistor to remain moderately conducting, such that the inductor current continues to flow through a main channel of the low-side transistor (instead of the body diode), thereby preventing or reducing the accumulation of reverse recovery charge.

The objectives, technical details, features, and effects of the present invention will be better understood with regard to the detailed description of the embodiments below, with reference to the attached drawings.

### BRIEF DESCRIPTION OF THE DRAWINGS

FIG. 1A illustrates a switching converter of prior art.

FIG. 1B illustrates an operating waveform diagram of prior art switching converter.

FIG. 2A and FIG. 2B illustrate block diagrams of switching converters in two embodiments of the present invention.

FIGS. 3A to 3C illustrate schematic diagrams of switching converters in various embodiments of the present invention.

FIG. 4 illustrates an operational waveform diagram of a switching converter in one embodiment of the present invention.

FIG. 5 illustrates an operating waveform diagram of a switching converter in another embodiment of the present invention.

FIG. 6 illustrates a schematic diagram of the amplifier circuit according to one specific embodiment of the present invention.

FIGS. 7A to 7G illustrate various embodiments of a power-stage circuit of the switching converter of the present invention.

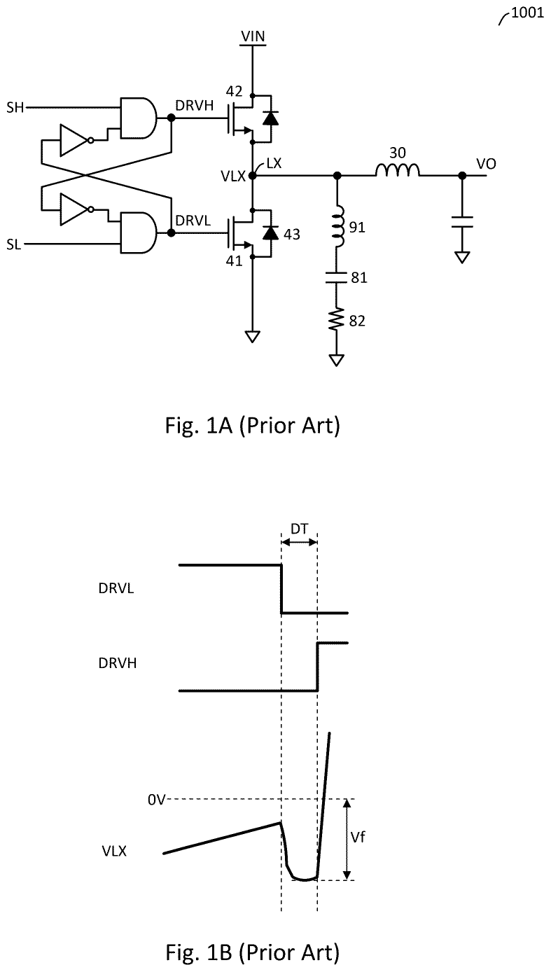

### DESCRIPTION OF THE PREFERRED EMBODIMENTS

The drawings as referred to throughout the description of the present invention are for illustration only, to show the interrelations between the circuits and the signal waveforms, but not drawn according to actual scale of circuit sizes and signal amplitudes and frequencies.

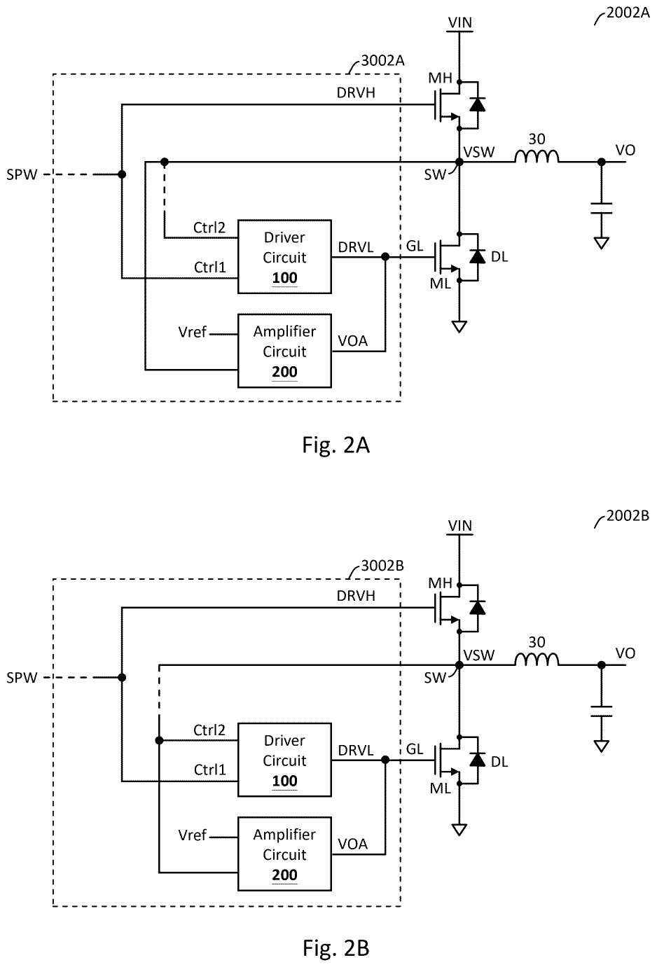

FIG. 2A and FIG. 2B illustrate block diagrams of switching converters in two embodiments of the present invention. In one embodiment, the switching converter of the present invention is configured as the switching converter 2002A in FIG. 2A. In another embodiment, the switching converter of the present invention is configured as the switching converter 2002B in FIG. 2B. As shown in FIG. 2A, in one embodiment, the switching converter 2002A includes a first transistor ML and a second transistor MH commonly coupled to a switching node SW, configured to switch an inductor 30 (i.e., to switch electrical connections of 30 between different states) according to a pulse-width modulation (PWM) signal SPW to convert an input voltage VIN into an output voltage VO. In one embodiment, a control circuit 3002A is configured to control the first transistor ML and the second transistor MH of the switching converter 2002A based on the PWM signal SPW. In this embodiment, the first transistor ML and the second transistor MH are both N-type metal-oxide-semiconductor (MOS) transistors.

In one embodiment, the control circuit 3002A includes a driver circuit 100 and an amplifier circuit 200. The driver circuit 100 is configured to generate a switching drive signal DRVL based on the PWM signal SPW and a switching signal VSW at the switching node SW to switch the first transistor ML. The amplifier circuit 200 is configured to amplify a difference between the switching signal VSW and a reference signal Vref during a dead time to generate an amplified output signal VOA, so as to control the first transistor ML through a linear negative feedback operation to regulate a voltage of the switching signal VSW to be not lower than a predetermined negative voltage, thereby preventing forward conduction of a body diode DL of the first transistor ML or reducing a reverse recovery charge of the body diode DL. In this embodiment, the switching drive signal DRVL and the amplified output signal VOA are both coupled to a gate GL of the first transistor ML.

It is noted that during the dead time mentioned above, the first transistor ML is controlled by the amplified output signal VOA to operate in a saturation region or a linear region to regulate the voltage of the switching signal VSW, while the second transistor MH is turned off. It is further noted that in one embodiment, an absolute value of the predetermined negative voltage is less than a forward conduction voltage (e.g., 0.7V) of the body diode DL of the first transistor ML, thereby preventing the body diode DL from forward conducting. Notably, even if some forward current still flows through the body diode DL, the reverse recovery charge can still be effectively reduced through the above control.

Still referring to FIG. 2A, in one embodiment, the driver circuit 100 is configured to generate the switching drive signal DRVL based on a first control signal Ctrl1 and a second control signal Ctrl2 to switch the first transistor ML. In this embodiment, the first control signal Ctrl1 is related to the PWM signal SPW, and the second control signal Ctrl2 is related to the switching signal VSW.

It is noted that the configuration of the switching converter 2002B in FIG. 2B is generally similar to that of the switching converter 2002A in FIG. 2A. The difference lies in that one input terminal of the amplifier circuit 200 in FIG. 2A is directly coupled to the switching signal VSW, while the corresponding input terminal in FIG. 2B is coupled to one of the input terminals of the driver circuit 100. The detailed structure will be described in later embodiments, and those skilled in the art can deduce the configuration from FIG. 2A and the following detailed embodiments.

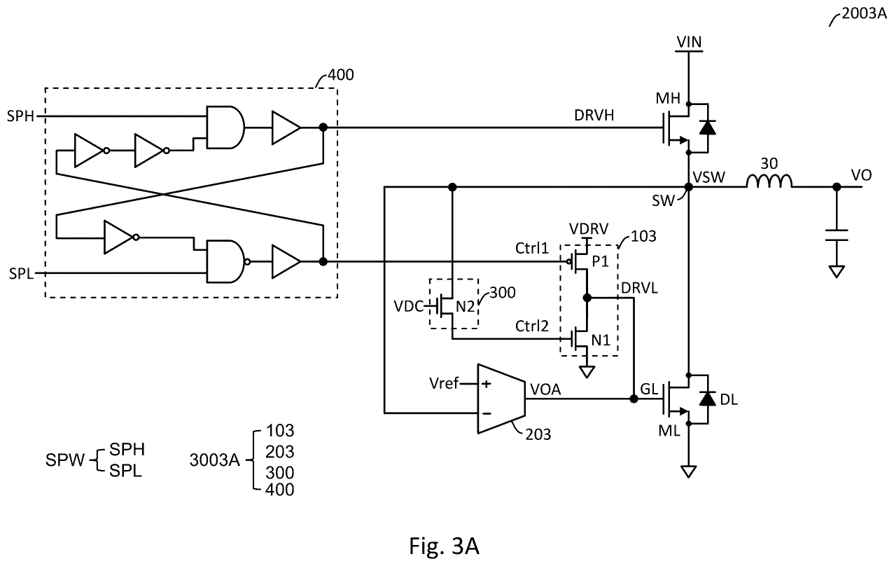

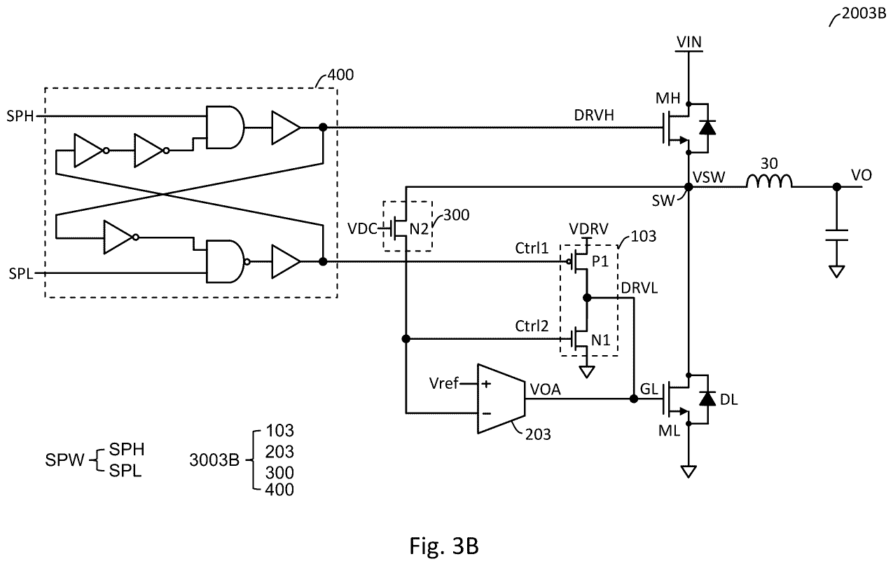

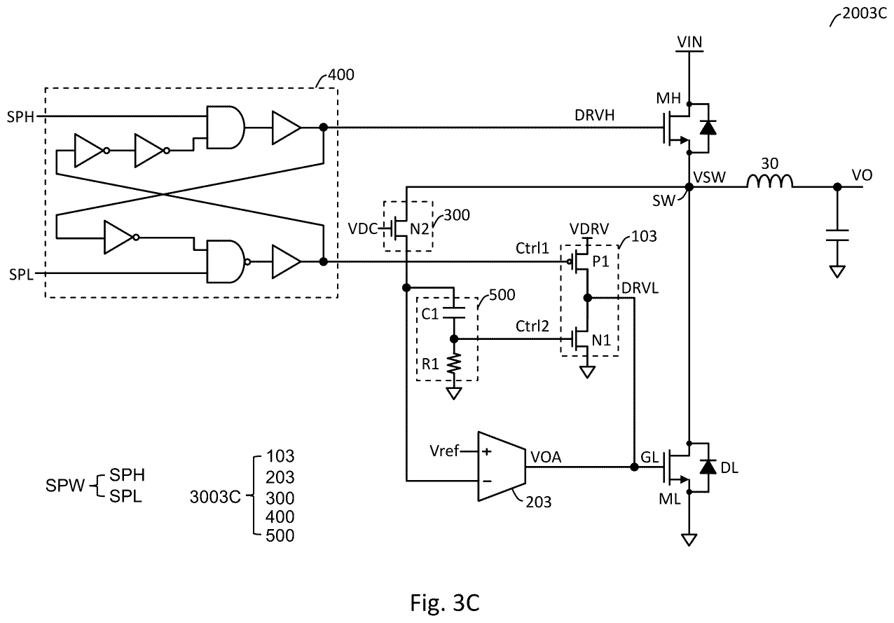

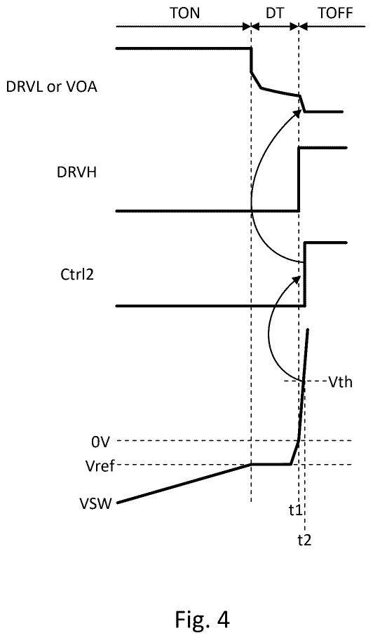

FIGS. 3A to 3C illustrate schematic diagrams of switching converters in various embodiments of the present invention. FIG. 4 illustrates an operational waveform diagram of a switching converter in one embodiment of the present invention. The switching converter 2003A in FIG. 3A corresponds to a specific embodiment of the switching converter 2002A in FIG. 2A. In one embodiment, as shown in FIG. 3A, a control circuit 3003A further includes a clamping circuit 300 and a non-overlapping circuit 400. In one embodiment, the PWM signal SPW includes signals SPH and SPL, and the non-overlapping circuit 400 includes plural logic gates configured to generate non-overlapping signals, including the switching drive signal DRVH and the first control signal Ctrl1 (Ctrl1 subsequently generates the switching drive signal DRVL), based on the signals SPH and SPL, for respectively controlling the second transistor MH and the first transistor ML.

In one embodiment, the clamping circuit 300 is configured to generate the second control signal Ctrl2 based on the switching signal VSW, and to clamp a level of the second control signal Ctrl2 not greater than a clamping voltage level. In a specific embodiment, the clamping circuit 300 includes a clamping transistor N2, which is an NMOS transistor with its gate controlled by a DC voltage VDC. In this embodiment, the clamping voltage level is a difference between the DC voltage VDC and a turn-on threshold voltage of the clamping transistor N2, and is lower than a maximum rated voltage of the second switch N1, thereby preventing a gate voltage of the second switch N1 from exceeding its maximum rated voltage and causing damage.

Still referring to FIG. 3A, in one embodiment, a driver circuit 103 includes a first switch P1 and a second switch N1, which are sequentially coupled in series between a driving voltage VDRV and a ground potential. In this embodiment, the first switch P1 is a PMOS transistor and the second switch N1 is an NMOS transistor. The gates of the first switch P1 and the second switch N1 are controlled by the first control signal Ctrl1 and the second control signal Ctrl2, respectively.

Referring to FIGS. 3A and 4 simultaneously, in one embodiment, as shown in FIG. 4, during an on time TON within a switching time, the first switch P1 controls the switching drive signal DRVL to be asserted according to the first control signal Ctrl1, meaning the switching drive signal DRVL has a high level (e.g., the driving voltage VDRV in this embodiment), thereby turning on the first transistor ML. In one embodiment, during an off time TOFF within the switching time, the second switch N1 controls the switching drive signal DRVL to be de-asserted according to the second control signal Ctrl2, meaning the switching drive signal DRVL has a low level (e.g., the ground potential in this embodiment), thereby turning off the first transistor ML.

It is noted that the switching time refers to a time outside the dead time DT, and includes the on time TON and the off time TOFF. It is further noted that during the switching time, the first transistor ML and the second transistor MH are complementarily switched under the control of the control circuit 3003A. Additionally, the on time TON and the off time TOFF in this disclosure respectively correspond to a turned-on state and a turned-off state of the first transistor ML.

In one embodiment, when the switching signal VSW exceeds a predetermined threshold voltage Vth (as shown at time t2 in FIG. 4), the second control signal Ctrl2 is asserted to turn on the second switch N1, thereby de-asserting the switching drive signal DRVL to turn off the first transistor ML. In the embodiment shown in FIG. 3A, the predetermined threshold voltage Vth corresponds to a turn-on threshold voltage of the second switch N1. As the switching signal VSW exceeds the predetermined threshold voltage Vth, the second control signal Ctrl2 becomes asserted, thereby turning on the second switch N1. In this embodiment, the predetermined threshold voltage Vth is greater than zero. From one perspective, when the dead time DT ends and the switching drive signal DRVH controls the second transistor MH to turn on (as shown at time t1 in FIG. 4), the voltage level of the switching signal VSW gradually increases. When the voltage of the switching signal VSW exceeds the predetermined threshold voltage Vth, the first transistor ML is turned off by the switching drive signal DRVL. Since the body diode DL of the first transistor ML has not been forward-conducting during the dead time DT, the reverse recovery charge of the body diode DL can be avoided or reduced during this state transition, thereby suppressing voltage spikes and shortening the transition time.

In one embodiment, the switching signal VSW is coupled to a negative input terminal of an amplifier circuit 203. In one embodiment, during the dead time DT shown in FIG. 4, the amplifier circuit 203 amplifies the difference between the switching signal VSW and the reference signal Vref to generate the amplified output signal VOA, so as to perform a linear negative feedback operation to control the first transistor ML such that the voltage of the switching signal VSW is regulated to be not lower than the predetermined negative voltage. In this embodiment, the absolute value of the predetermined negative voltage is less than the forward conduction voltage of the body diode DL of the first transistor ML (e.g., 0.7V), thereby preventing forward conduction of the body diode DL or reducing its reverse recovery charge.

It is noted that in one embodiment, during the dead time DT, the switching drive signal DRVL is in a high output impedance state (both the first switch P1 and the second switch N1 are off), and the gate GL of the first transistor ML is primarily controlled by the amplified output signal VOA. In the embodiment of FIG. 3A, during the switching time (including the on time TON and the off time TOFF) outside the dead time DT, the switching drive signal DRVL is in a low output impedance state (either the first switch P1 or the second switch N1 is on), and the gate GL of the first transistor ML is primarily controlled by the switching drive signal DRVL.

FIG. 3B illustrates a specific embodiment of the switching converter 2002B of FIG. 2B. The control circuit 3003B is similar to the control circuit 3003A, except that in one embodiment, as shown in FIG. 3B, the negative input terminal of the amplifier circuit 203 and the second control signal Ctrl2 are commonly coupled to the clamping circuit 300. The clamping circuit 300 is further configured to clamp the negative input terminal of the amplifier circuit 203 to be not greater than the clamping voltage level, thereby preventing the amplifier circuit 203 from damage caused by exceeding its maximum rated voltage. Other operating details of FIG. 3B can be deduced from the descriptions of FIG. 3A and FIG. 4.

FIG. 3C illustrates another specific embodiment of the switching converter 2002B of FIG. 2B. In one embodiment, as shown in FIG. 3C, the control circuit 3003C further includes a high-pass filter circuit 500 coupled between the clamping circuit 300 and the second control signal Ctrl2, configured to high-pass-filter the switching signal VSW to generate the second control signal Ctrl2. When the switching signal VSW includes a high-frequency component, a high-pass pulse of the second control signal Ctrl2 is generated to rapidly turn on the second switch N1, thereby de-asserting the switching drive signal DRVL (e.g., pulled to a low level) and turning off the first transistor ML. In one embodiment, the amplifier circuit 203 simultaneously maintains the amplified output signal VOA in a disabled state based on the difference between the switching signal VSW and the reference signal Vref, such that the first transistor ML remains off.

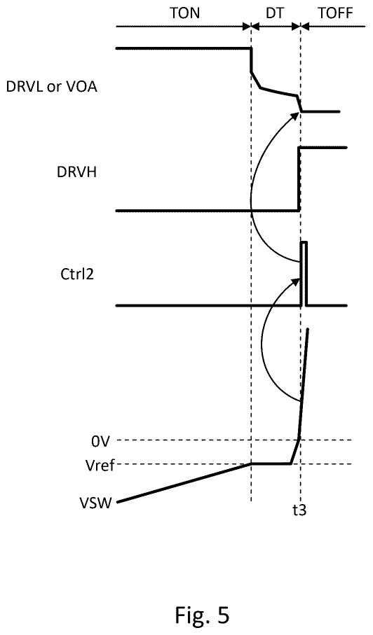

Referring to FIG. 3C and FIG. 5, FIG. 5 illustrates an operating waveform diagram of a switching converter in another embodiment of the present invention. In one specific embodiment, at time t3 in FIG. 5, a level of the switching signal VSW rapidly increases, and the second control signal Ctrl2 generates a pulse to turn on the second switch N1 and de-asserts the switching drive signal DRVL, thereby turning off the first transistor ML. After the first transistor ML is turned off, it remains off under control of the amplified output signal VOA.

It is noted that, in the embodiment of FIG. 3C, at time t3, the pulse of the second control signal Ctrl2 causes the second switch N1 to turn on, thereby de-asserting the switching drive signal DRVL and turning off the first transistor ML. Subsequently, the first transistor ML remains off under control of the amplified output signal VOA. In this embodiment, within the off time TOFF of the switching time, after the pulse of the second control signal Ctrl2 ends, the switching drive signal DRVL becomes high output impedance state, and the gate GL of the first transistor ML is primarily controlled by the amplified output signal VOA.

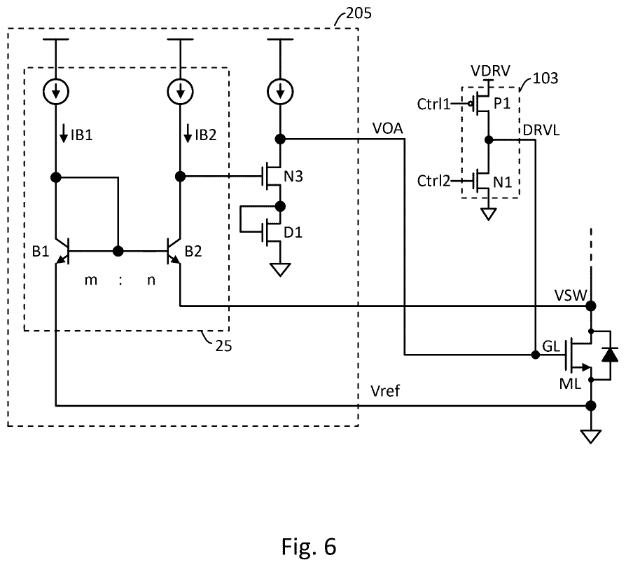

FIG. 6 illustrates a schematic diagram of the amplifier circuit according to one specific embodiment of the present invention. In one embodiment, the amplifier circuit includes a common-base amplifier or a common-gate amplifier and has an input offset voltage, which is related to the predetermined negative voltage. In the embodiment shown in FIG. 6, the amplifier circuit 205 includes a common-base amplifier 25 including transistors B1 and B2 (e.g., both being NPN bipolar junction transistors), with their emitters respectively coupled to ground and to the switching signal VSW. In this embodiment, the reference signal Vref is physically coupled to ground, and the current density of transistor B1 is less than that of transistor B2, such that the common-base amplifier 25 has the input offset voltage based on the predetermined negative voltage, such that the switching signal VSW is regulated to be not lower than the predetermined negative voltage, thereby preventing forward conduction of the body diode DL of the first transistor ML or reducing its reverse recovery charge.

It should be noted that the current density of transistor B1 is less than that of transistor B2, which can be achieved through the following implementations. In one specific embodiment, the area ratio of transistors B1 to B2 is m:n (m and n>0). When the currents IB1 and IB2 flowing through B1 and B2 are equal, the area ratio is configured with m>n to make the current density of transistor B1 lower than that of transistor B2. In another embodiment, when the areas of transistors B1 and B2 are equal (i.e., m=n), the current IB1 is configured to be less than the current IB2, achieving a lower current density in the transistor B1. In other embodiments, both area and current ratios can be combined to achieve the desired current density difference.

In one embodiment, as shown in FIG. 6, the amplifier circuit 205 includes a pull-down transistor N3 and a clamping transistor D1, which are sequentially connected in series between the amplified output signal VOA and the ground potential. In this embodiment, the clamping transistor D1 is configured as a diode-connected transistor, wherein a gate and a drain of D1 are connected to form the diode-connected transistor configuration. The pull-down transistor N3 is configured to provide a pull-down driving force for the amplified output signal VOA based on the difference between the switching signal VSW and the reference signal Vref. The clamping transistor D1 is configured to clamp the amplified output signal VOA to be not lower than a predetermined level, which is higher than a turn-on threshold voltage of the first transistor ML. Specifically, by clamping the amplified output signal VOA to be not lower than the turn-on threshold voltage of the first transistor ML, the timing for turning off the first transistor ML is determined by the second switch N1 in the driver circuit 103. It should be noted that this embodiment corresponds specifically to the embodiments in FIG. 3A and FIG. 3B.

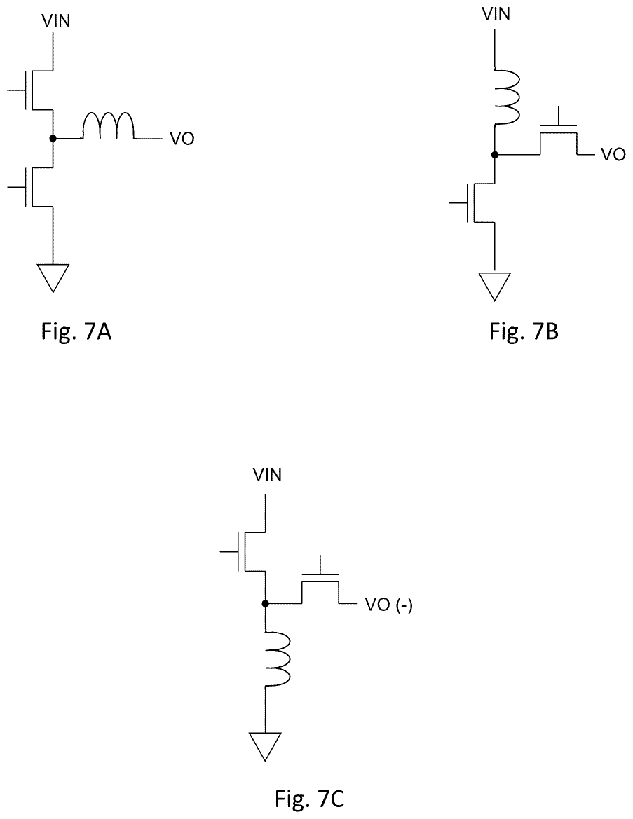

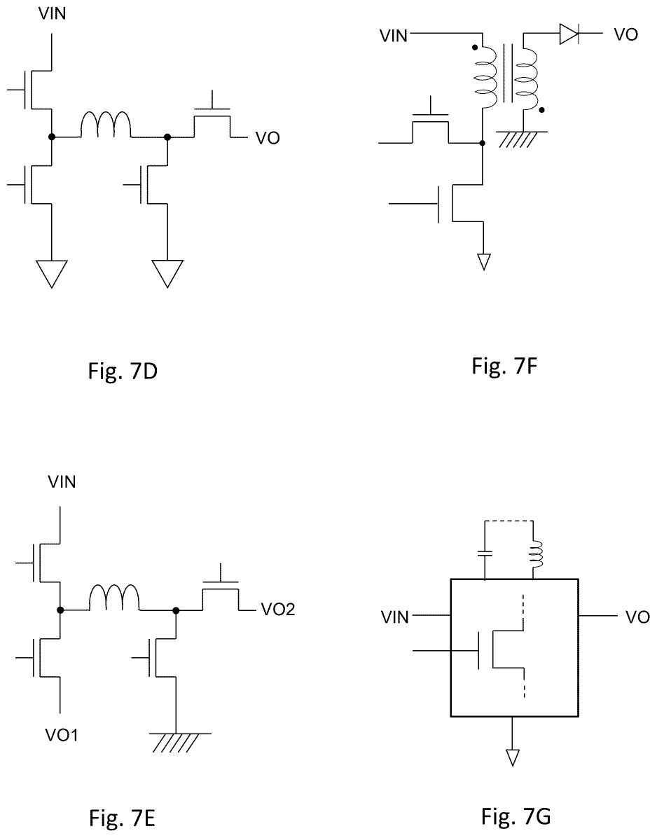

FIGS. 7A to 7G illustrate various embodiments of a power-stage circuit of the switching converter of the present invention. The power-stage circuit of the switching converter of the present invention includes at least one switch and an inductor coupled to each other, wherein the at least one switch switches the inductor according to a control signal so as to convert the input voltage into the output voltage. As shown in FIGS. 7A to 7G, the power-stage circuit may be, but not limited to, a synchronous buck converter, a synchronous boost converter, a buck-boost converter, a half-bridge flyback converter, or a full-bridge or half-bridge switched-resonant converter.

In summary, according to the present invention, during the switching time, the conduction state of the low-side transistor is controlled by the driver circuit; while during the dead time, the switching drive signal enters a high impedance state, and the conduction state of the low-side transistor is controlled by the amplifier circuit, which regulates the switching signal at the switching node to be not lower than a predetermined negative voltage, thereby preventing forward conduction of the body diode or reducing its reverse recovery charge. Furthermore, after the high-side transistor is turned on, the driver circuit turns off the low-side transistor, further suppressing voltage spikes and EMI noise. This design effectively prevents voltage spikes caused by reverse recovery of the body diode without relying on power-consuming filter circuits, thereby improving overall power efficiency.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, to perform an action “according to” a certain signal as described in the context of the present invention is not limited to performing an action strictly according to the signal itself, but can be performing an action according to a converted form or a scaled-up or down form of the signal, i.e., the signal can be processed by a voltage-to-current conversion, a current-to-voltage conversion, and/or a ratio conversion, etc. before an action is performed. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. A control circuit configured to control a switching converter based on a pulse-width modulation (PWM) signal, wherein the switching converter includes a first transistor and a second transistor commonly coupled to a switching node, configured to switch an inductor according to the PWM signal to convert an input voltage into an output voltage; the control circuit comprising:
a driver circuit configured to generate a switching drive signal based on the PWM signal and a switching signal at the switching node, thereby switching the first transistor; and
an amplifier circuit configured to amplify a difference between the switching signal and a reference signal during a dead time to generate an amplified output signal, and configured to control the first transistor through a linear negative feedback operation to regulate a voltage of the switching signal to be not lower than a predetermined negative voltage.

2. The control circuit of claim 1, wherein the driver circuit is configured to generate the switching drive signal based on a first control signal and a second control signal, thereby switching the first transistor; wherein the first control signal is related to the PWM signal, and the second control signal is related to the switching signal;
wherein during the dead time, the switching drive signal is in a high output impedance state, such that the first transistor is primarily controlled by the amplified output signal;
wherein during a switching time outside the dead time, the switching drive signal is in a low output impedance state, such that the first transistor is primarily controlled by the switching drive signal.

3. The control circuit of claim 2, wherein the driver circuit includes a first switch and a second switch;
wherein during an on time within the switching time, the first switch controls the switching drive signal to be asserted according to the first control signal, such that the first transistor is on;
wherein during an off time within the switching time, the second switch controls the switching drive signal to be de-asserted according to the second control signal, thereby turning off the first transistor.

4. The control circuit of claim 3, wherein when the switching signal exceeds a predetermined threshold voltage, the second control signal controls the switching drive signal to be de-asserted, thereby turning off the first transistor.

5. The control circuit of claim 4, wherein a gate of the second switch is controlled by the second control signal, and the second control signal is coupled to the switching signal, wherein the predetermined threshold voltage corresponds to a turn-on threshold voltage of the second switch.

6. The control circuit of claim 3, further comprising: a clamping circuit configured to generate the second control signal based on the switching signal, and to clamp the second control signal, such that a level of the second control signal is not greater than a clamping voltage level.

7. The control circuit of claim 6, wherein the clamping voltage level is lower than a maximum rated voltage of the second switch.

8. The control circuit of claim 6, further comprising: a high-pass filter circuit coupled between the clamping circuit and the second control signal, configured to high-pass-filter the switching signal to generate the second control signal, such that when the switching signal includes a high-frequency component, the second switch controls the switching drive signal to be de-asserted, thereby turning off the first transistor.

9. The control circuit of claim 8, wherein after the first transistor is turned off, the amplifier circuit maintains the amplified output signal in a disabled state based on the difference between the switching signal and the reference signal, such that the first transistor remains off.

10. The control circuit of claim 1, wherein an absolute value of the predetermined negative voltage is less than a forward conduction voltage of a body diode of the first transistor.

11. The control circuit of claim 1, wherein the amplifier circuit includes a common-base amplifier or a common-gate amplifier and has an input offset voltage, wherein the input offset voltage is related to the predetermined negative voltage.

12. The control circuit of claim 1, wherein the amplified output signal is clamped to be not lower than a predetermined level, wherein the predetermined level is higher than a turn-on threshold voltage of the first transistor.

13. The control circuit of claim 12, wherein the amplifier circuit includes a pull-down transistor and a clamping transistor serially connected to the amplified output signal, wherein the pull-down transistor is configured to provide a pull-down driving force for the amplified output signal based on the difference between the switching signal and the reference signal, and the clamping transistor is configured as a diode-connected transistor.

14. A control method for controlling a switching converter based on a pulse-width modulation (PWM) signal, wherein the switching converter includes a first transistor and a second transistor commonly coupled to a switching node, configured to switch an inductor according to the PWM signal to convert an input voltage into an output voltage, the control method comprising:
generating a switching drive signal based on the PWM signal and a switching signal at the switching node, thereby switching the first transistor; and
amplifying a difference between the switching signal and a reference signal during a dead time to generate an amplified output signal;
wherein a step of generating the amplified output signal includes:
controlling the first transistor through a linear negative feedback operation to regulate a voltage of the switching signal to be not lower than a predetermined negative voltage.

15. The control method of claim 14, wherein a step of generating the switching drive signal includes generating the switching drive signal based on a first control signal and a second control signal, thereby switching the first transistor; wherein the first control signal is related to the PWM signal, and the second control signal is related to the switching signal;
during the dead time, rendering the switching drive signal a high output impedance state, so as to primarily control the first transistor by the amplified output signal; and
during a switching time outside the dead time, rendering the switching drive signal a low output impedance state, so as to primarily control the first transistor by the switching drive signal.

16. The control method of claim 15, wherein the step of generating the switching drive signal includes:
during an on time within the switching time, asserting the switching drive signal based on the first control signal, thereby turning on the first transistor; and
during an off time within the switching time, de-asserting the switching drive signal based on the second control signal, thereby turning off the first transistor.

17. The control method of claim 16, wherein the step of generating the switching drive signal includes: when the switching signal exceeds a predetermined threshold voltage, controlling the switching drive signal to be de-asserted, thereby turning off the first transistor.

18. The control method of claim 15, further comprising:
generating the second control signal based on the switching signal and clamping the second control signal such that a level of the second control signal is not greater than a clamping voltage level.

19. The control method of claim 18, further comprising:
high-pass-filtering the switching signal to generate the second control signal; and
when the switching signal includes a high-frequency component, controlling the switching drive signal to be de-asserted, thereby turning off the first transistor.

20. The control method of claim 19, wherein the step of generating the amplified output signal includes: after the first transistor is turned off, maintaining the amplified output signal in a disabled state based on the difference between the switching signal and the reference signal, such that the first transistor remains off.

21. The control method of claim 14, wherein an absolute value of the predetermined negative voltage is less than a forward conduction voltage of a body diode of the first transistor.

22. The control method of claim 14, wherein generating the amplified output signal includes: clamping the amplified output signal to be not lower than a predetermined level, wherein the predetermined level is higher than a turn-on threshold voltage of the first transistor.
